(19) United States
(12) Patent Application Publication
(10) Pub. No.: US 2014/0216513 A1
(43) Pub. Date: Aug. 7, 2014

(54) HIGH ZT THERMOELECTRIC WITH REVERSIBLE JUNCTION

(71) Applicant: Joseph V. Mantese, Ellington, CT (US)

(72) Inventor: Joseph V. Mantese, Ellington, CT (US)

(73) Assignee: United Technologies Corporation, Hartford, CT (US)

(21) Appl. No.: 14/346,181

(22) PCT Filed: Sep. 23, 2011
(86) PCT No.: PCT/US11/53014

§ 371 Date: Mar. 20, 2014

(51) Int. Cl. H01L 35/32; H01L 35/34

(52) U.S. Cl. CPC H01L 35/32; H01L 35/34
USPC 136/200; 438/54

(57) ABSTRACT

A composite structure with tailored anisotropic energy flow is described. The structure consists of an array of two-dimensional electrodes with anisotropic geometrical shapes on a semiconductor or semimetal layer that in turn is on a metal baselayer. An applied voltage between the two-dimensional electrode array and the baselayer renders the regions under the electrodes insulating such that the anisotropic regions interact with energy flow in the semiconductor or semimetal layer. Depending on the orientation of the anisotropic insulating regions with respect to the principal direction of energy flow, the energy flow in the semiconductor or semimetal layer is greater in a principal direction and is lower in an opposite direction.

### BACKGROUND

This invention relates to composite materials containing obstacles to energy flow with anisotropic geometrical shapes in general and, more particularly, to composite materials with tailored anisotropic electrical and thermal conductivities.

The ability to control the direction and magnitude of energy flow in one dimension (wire), two dimension (thin film), and three dimension (bulk) solid state components has been considered critical to device performance since the beginning of the electronic age. Diodes and other electronic valves are principal examples. Another example where directionality of thermal and electrical currents affect performance is in thermoelectric devices. The dimensionless thermoelectric figure of merit is a measure of performance and is given by the following equation:

$$ZT = \frac{{S}^{2} σ T}{K} ,$$

where S, σ, K and T are the Seebeck coefficient, electrical conductivity, thermal conductivity and absolute temperature respectively.

The thermoelectric figure of merit is also related to the strength of interaction between the carriers and vibrational modes of the lattice structure (phonons) and available carrier energy states which, in turn, are a function of the materials used in the thermoelectric component. As such, the thermal conductivity, K, has an electronic component (K_{E}), associated with the electronic carriers and a lattice component (K_{L}) associated with thermal energy flow due to phonons. The thermal conductivity can then be expressed as K=K_{E}+K_{L}, and the figure of merit can be expressed generally as

$$ZT = \frac{{S}^{2} σ T}{{K}_{E} + {K}_{L}} .$$

Efforts to improve the performance of thermoelectric materials have generally focused on reducing K and maximizing σ. Unfortunately, the two quantities are closely coupled, and changing one typically results in corresponding changes in the other.

Recent efforts to improve thermoelectric performance without sacrificing electrical conductivity have focused on inserting physical obstacles with nano scaled dimensions in thermoelectric structures to presumably impede phonon propagation. Venkata Subramanian et al. U.S. Pat. No. 7,342,169 teach that superlattice structures with nano scale dimensions block phonon transmission while allowing electron transmission thereby raising ZT and is incorporated herein in its entirety by reference. Harmon et al. U.S. Pat. No. 6,605,772 disclose that quantum dot superlattices (QDSL) of thermoelectric materials exhibit enhanced ZT values at room temperature also by blocking phonon transmission and is incorporated herein in its entirety by reference. Heremans et al. U.S. Pat. No. 7,365,265 and U.S. Publication No. 2004/0187905 disclose that nano scale inclusions on the order of 100 nm in size presumably block phonon transmission in lead telluride (PbTe) and other thermoelectric materials, thereby significantly improving the Seebeck coefficient.

Other physical obstacles to energy flow in solids have been disclosed. K. Song et al., Physical Review Letters, Vol. 80, 3831 (1998), demonstrate that an asymmetric artificial scatterer in a semiconductor microjunction deflects ballistic electrons causing nonlinear transport and current voltage (IV) rectification and is incorporated herein in its entirety by reference.

Asymmetric energy flow in materials is a useful property with a multitude of applications not limited to thermoelectric materials.

### SUMMARY

In accordance with this invention, a composite structure has tailored anisotropic energy flow. The structure comprises a semiconducting or semimetal layer on a metal baselayer. An array of two-dimensional electrodes with anisotropic geometrical shapes is on the semiconductor or semimetal layer. When a voltage is applied to the two-dimensional electrodes and baselayer, the regions under the electrodes become insulating and interact with the energy flow in the semiconducting or semimetal layer. Depending on how the major axes of the two-dimensional anisotropic electrodes are oriented with respect to the principal direction of energy flow, the energy flow in the principle direction is greater than in an opposite direction. By orienting the inclusions in different directions, tailored anisotropic electrical and thermal conductivity can be achieved.

In one aspect of this invention, the semiconducting or semimetal material is doped silicon or graphene. In another aspect of this invention, the semiconducting or semimetal material is a thermoelectric material and the composite structure has a high thermoelectric figure of merit ZT.

In another aspect of this invention, the electrodes with anisotropic shapes are arranged in single or multiple rows oriented perpendicular to the principal directions of energy flow in the composite structure.

In another aspect of this invention, the spacing of the rows of electrodes is on the order of the mean free path of charge carriers in the energy flow.

In another aspect of this invention, a method of forming a composite structure with anisotropic energy flow is described.

### BRIEF DESCRIPTION OF THE DRAWINGS

FIG. 1A is a schematic cross section of a composite multilayer structure of the invention.

FIG. 1B is the schematic cross section of FIG. 1A with a voltage applied between the electrodes and the metal base layer.

FIG. 2 is a schematic showing an array of electrodes with anisotropic geometrical shapes.

FIG. 3 is a schematic showing an array of electrodes with reversible anisotropic geometrical shapes.

FIG. 4 is a schematic showing an array of electrodes with anisotropic geometrical shapes.

FIG. 5 is a diagram showing a method of forming a composite structure with tailored anisotropic energy flow.

### DETAILED DESCRIPTION

The present invention is generally directed to a method of imparting anisotropic thermal and electrical conductivity in a composite multilayer structure by creating obstacles to energy flow with anisotropic geometrical shapes. The anisotropic energy flow is directly related to the orientation of the principal axis of the obstacles with respect to the principal direction of energy flow.

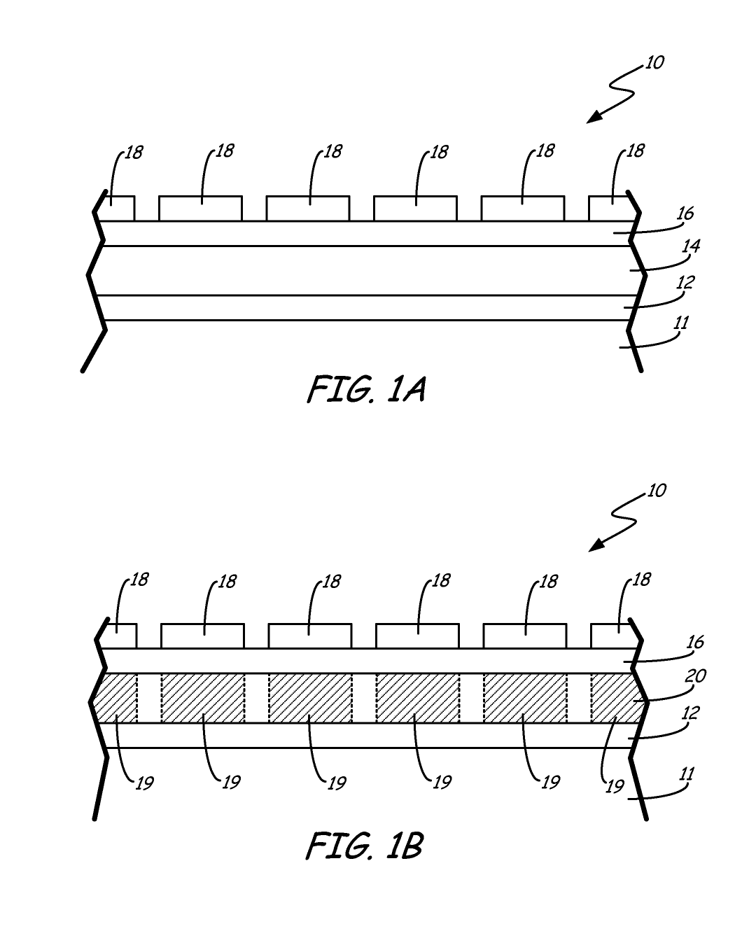

A schematic cross section of composite multilayer structure 10 of the invention is shown in FIG. 1A. Multilayer structure 10 comprises substrate 11, base metal conducting layer 12, semiconducting or semimetal layer 14, insulating layer 16, and metallic electrodes 18. The purpose of electrodes 18 is to create insulating islands 19 in layer 14 upon the application of an applied voltage between electrodes 18 and base metal conducting layer 12 as shown in FIG. 1B. The applied voltage causes an inversion or depletion of the carrier concentration of the semiconductor or semimetal effectively producing an insulating region in a semiconducting or semimetal matrix underneath the electrodes. The effect is described by Colinge et al. in Nature Nanotechnology, 2010, and is incorporated herein in its entirety by reference.

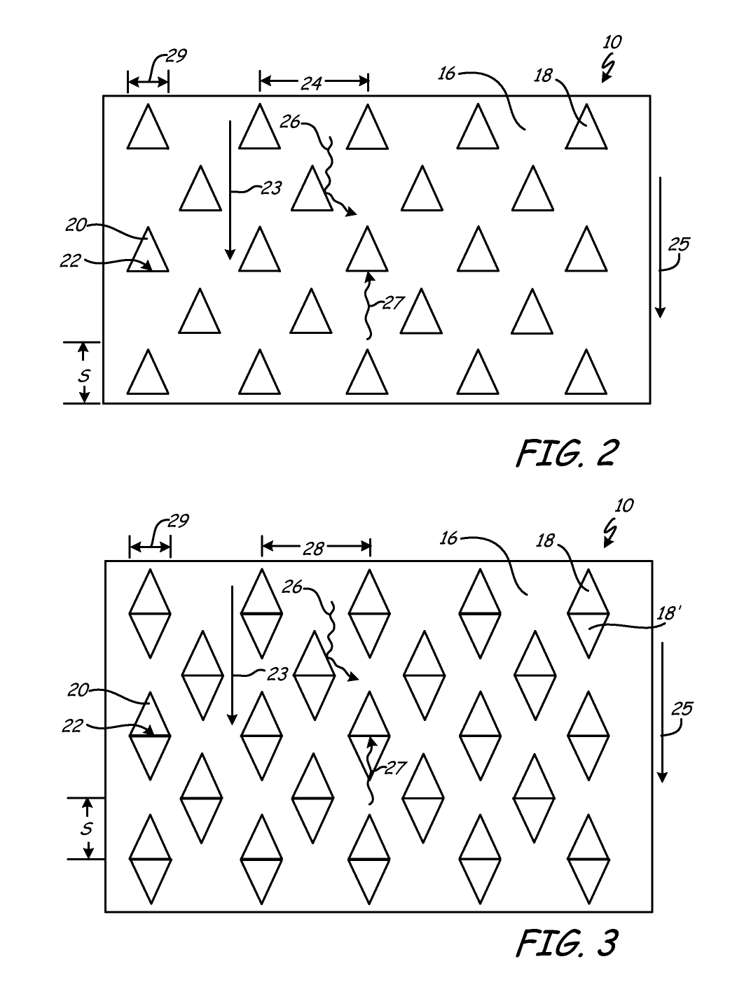

The invention described herein is a two-dimensional analog of commonly owned U.S. 2010/0044644, which is incorporated herein in its entirety by reference. Geometrical aspects of the relation between the insulating islands with anisotropic geometrical shapes are illustrated in the embodiment shown in FIG. 2, which is a schematic drawing showing a top view of composite multilayer structure 10. In this embodiment, electrodes 18 have triangular shapes which have an apex 20 and a base 22. Base 22 is wider than apex 20, thereby imparting asymmetric symmetry to the insulating obstacles under electrodes 18 upon the application of a voltage applied between electrodes 18 and base metal conducting layer 12. In the example, energy flow is depicted as arrow 23 in the principal direction of the flow. Apex 20 is upstream in the energy flow and base 22 is downstream in the energy flow. Arrow 25 depicts driving force for energy flow 23. Driving force 25 comprises, for instance, an electrical potential if energy flow 23 is electrical energy and, for instance, a temperature gradient if energy flow 23 is thermal energy. Electrical energy propagates through layer 14 in the form of electrons and holes and thermal energy propagates in the form of elastic waves as phonons. Schematic wavy arrow 26 depicts deflections of energy carriers and energy flow 23 due to shaped sides of insulating islands 19 under electrodes 18 as the energy carriers encounter insulating islands 19.

If the driving force for energy flow is reversed, the energy carriers encounter obstacles (insulating regions 19) where deflection is not possible, and the barriers to energy flow are higher. This is schematically illustrated by wavy arrow 27. Thus, the rate of energy flow in the direction of arrow 23 is higher than in the opposite direction due to the anisotropic obstacle strength of the asymmetric insulating islands 19 if driving force 23 and subsequent energy flow 25 were reversed.

In the embodiment shown in FIG. 2, electrodes 18 are in parallel arrays at spacing S. Electrodes 18 are spaced apart at distance 24 in an arrangement where obstacle width 29 is sufficiently less than spacing 24, such that there is a finite areal density of unobstructed line of sight path through composite structure 10, such that some energy carriers 26 and energy flow 23 can pass through composite structure 10 unimpeded without encountering an obstacle.

In another embodiment, shown in FIG. 3, triangular electrodes 18′ are added to structure 10 to form obstacle patterns that can be reversed. If the scattering is specular at the insulating islands under electrodes 18 and 18′, then the structure will yield a σ to K_{E} ratio that will be greater or less than 1 depending on whether electrodes 18 or 18′ are turned on or off. As a result, the favorable direction of current and thermal flow may be adjusted electronically.

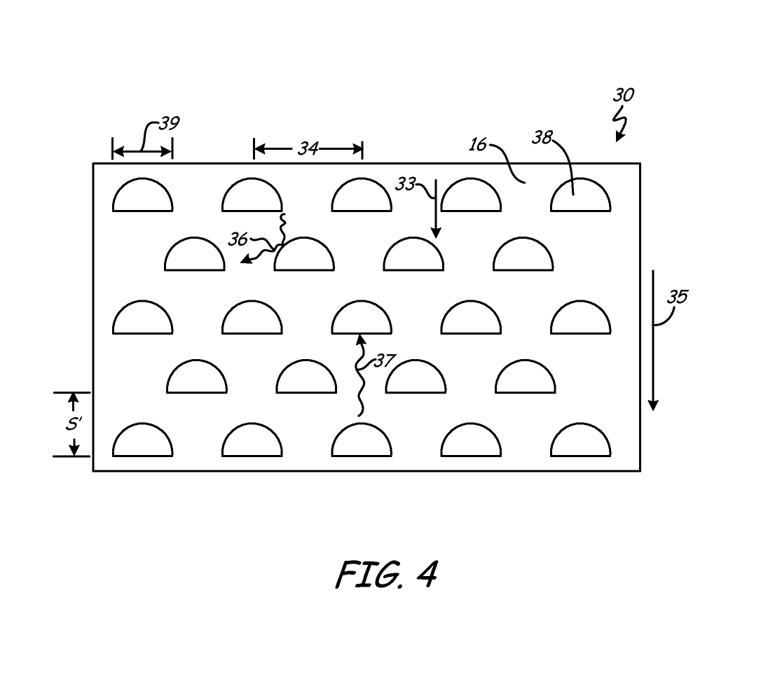

In the embodiment shown in FIG. 4, composite multilayer structure 30 contains semicircular electrodes 38. Schematic wavy arrow 36 depicts deflections of energy carriers from asymmetric insulating islands 19 under electrodes 38 due to shaped sides of insulating islands 19. Electrodes 38 are in parallel arrays at spacing S′. Electrodes 38 are spaced apart at distance 34 in an arrangement where obstacle width 39 is sufficiently large compared to spacing 34, such that there is no areal density where energy flow 33 can migrate through composite structure 30 without encountering an insulating obstacle 19 under electrodes 38 in a line of sight path. On the other hand, energy deflection as indicated by wavy arrow 36 still has a vector component in the downward direction after impacting an obstacle allowing energy flow.

If the driving force for energy flow 35 is reversed, the energy carriers encounter obstacles (insulating regions 19) where deflection is not possible and the barriers to energy flow are higher. This is schematically illustrated by wavy arrow 37. Thus, the rate of energy flow in the direction of arrow 33 is higher than in the opposite direction due to the anisotropic obstacle strength of the asymmetric inclusions if driving force 35 and subsequent energy flow 33 were reversed.

In other embodiments of the invention, the electrodes with anisotropic geometrical shapes can be trapezoids or other regular or irregular shapes wherein the base cross sectional length is larger than the peak cross sectional length along a principal axis of the electrode in the direction of energy flow.

To be effective as anisotropic barriers of electrical and thermal energy propagation, the barrier size and spacing need to be commensurate with the wavelength and mean free path of the carriers (i.e., electrons, holes, phonons) themselves. These quantities all have submicron dimensions.

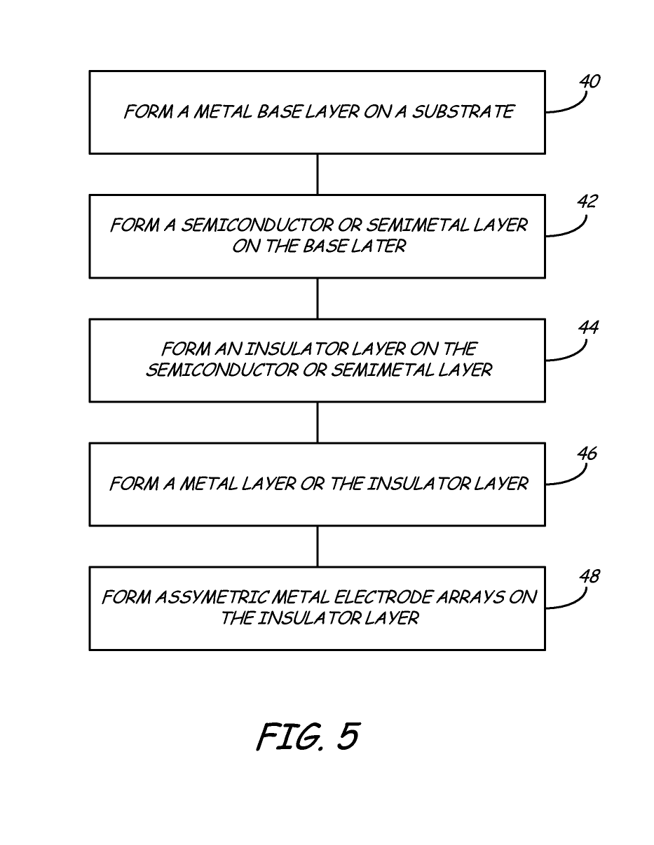

The composite multilayer structure of the present invention is produced according to the process shown in FIG. 5. To start, a metal base layer is formed on a substrate (Step 40). Forming techniques include, but are not limited to, physical vapor deposition (PVD), chemical vapor deposition (CVD), plasma enhanced CVD, molecular beam epitaxy (MBE), plating, or other deposition techniques known to those in the art. Substrate materials include silicon, silicon oxide, aluminum oxide, zirconium oxide, aluminum nitride, glass, polymers, and others known to those in the art. The metal base layer can be formed of aluminum, copper, platinum, indium tin oxide, indium antimony oxide, doped polysilicon, and other electrode materials known to those in the art. The thickness of the metal baselayer may be from 0.001 microns to 1 micron.

In the next step, a semiconductor or semimetal layer is formed on the metal baselayer. Candidates for the semiconductor or semimetal layer can be any material that exhibits thermoelectric behavior. Preferred materials for this invention are graphene, doped silicon, gallium arsenide, gallium antimonide, gallium nitride, aluminum nitride, bismuth telluride, antimony bismuth telluride, bismuth, and mixtures thereof. The thickness of the semiconductor or semimetal layer may be from 0.001 microns to 10.0 microns.

Graphene, in particular, has a known Seebeck coefficient that is two orders of magnitude higher than the best bulk thermoelectric materials known to date. The properties of graphene are described by Giem et al. in Nature Materials, Vol. 6, p. 183 (2007) and incorporated herein in its entirety as reference.

The semiconductor or semimetal layer can be formed by physical vapor deposition (PVD), chemical vapor deposition (CVD), plasma enhanced CVD, molecular beam epitaxy (MBE), or other techniques known to those in the art. Graphene is a special case in that it is a true two-dimensional crystal. As noted by Giem et al., techniques to make graphene have been successful and commercial sources are becoming available.

An insulator layer is then formed on the semiconductor or semimetal layer (Step 44). Deposition techniques include, but are not limited to, PVD, CVD, plasma enhanced CVD, MBE, or other techniques known to those in the art. Insulator layer 16 can be aluminum oxide, AlOₓ, silicon oxide, magnesium oxide, beryllium oxide, yttrium oxide, hafnium oxide, boron nitride, aluminum nitride, silicon nitride, silicon carbide, silicon oxynitride, diamond, and others known to those in the art. The thickness of insulator layer 16 may be from 0.001 microns to 1.0 micron.

A metal layer is then formed on the insulator layer (Step 46). The metal layer is formed from the same materials and by the same process used to form metal baselayer 12.

Asymmetric anisotropic metal electrode arrays 18 are then formed on insulator layer 16 (Step 48). The arrays may be formed by a standard photolithographic process of (i) applying photoresist, (ii) exposing and developing a pattern on the photoresist, (iii) removing undeveloped photoresist, (iv) etching exposed areas to remove metal, and (v) removing exposed photoresist to reveal anisotropic electrode array 18 or by other forming processes known to those in the art.

Other steps such as interconnecting and insulating baselayer 12 and electrodes 18 to form a working structure have been omitted for clarity.

It is important to note at this point that a single structure 10 comprising baselayer 12, semiconducting or semimetal layer 14, insulator layer 16, and asymmetrical geometrical electrode 18 arrays has been taught. A working device with asymmetrical conductivity for, for instance, thermoelectric application will comprise many layers of structure 10 to support predetermined system requirements.

While the invention has been described with reference to an exemplary embodiment(s), it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment(s) disclosed, but that the invention will include all embodiments falling within the scope of the appended claims.

1. A composite material comprising:
at least one semiconductor or semimetal layer on a conductor layer;
at least one insulator layer on the semiconductor or semimetal layer;
an array of two dimensional electrodes with anisotropic geometrical shapes on the insulator layer wherein the anisotropic geometrical shapes have a base length that is longer than a peak length along a principal axis of the electrodes in a first direction of energy flow wherein the peak length is upstream in the energy flow and the base length is downstream in the energy flow in the composite material such that, when a voltage is applied between the electrodes and conductor layer, the regions under the electrodes become insulating and interact with the energy flow in the composite material such that conductivity of energy through the composite material is greater in the first direction than in a second opposite direction.

2. The composite material of claim 1, wherein the electrodes with anisotropic shapes are dispersed in single or multiple rows oriented perpendicular to the principal directions of energy flow in the material.

3. The composite material of claim 2, wherein the spacing of the rows of electrodes is on an order of a mean free path of the charge carriers in the energy flow.

4. The composite material of claim 1, wherein a second array of electrodes is formed on the insulator layer with base lengths and peak lengths oriented along a principal axis directly opposite to that of the first axis to manage energy flow in a second opposite direction to the first direction.

5. The composite material of claim 1, wherein the electrodes with anisotropic shapes are triangles, trapezoids, semicircles, or semiellipses.

6. The composite material of claim 1, wherein the semiconductor or semimetal layer is a n-type or p-type semiconductor.

7. The composite material of claim 5, wherein the semiconductor or semimetal is selected from the group consisting of graphene, doped silicon, gallium arsenide, gallium antimonide, gallium nitride, aluminum nitride, bismuth telluride, antimony bismuth telluride, bismuth and mixtures thereof.

8. The composite material of claim 7, wherein the semiconductor or semimetal is a thermoelectric material and the composite has a ZT figure of merit greater than or equal to 0.5 at room temperature.

9. The composite material of claim 1, wherein the conductor layer and electrodes are selected from the group consisting of aluminum, copper, platinum, indium tin oxide, indium antimony oxide, doped polysilicon, and alloys and mixtures thereof.

10. The composite material of claim 1, wherein the insulating layer is selected from the group consisting of aluminum oxide, AlOₓ, silicon oxide, magnesium oxide, beryllium oxide, yttrium oxide, hafnium oxide, boron nitride, aluminum nitride, silicon nitride, silicon carbide, silicon oxynitride, diamond, and mixtures thereof.

11. The composite material of claim 1, wherein the major dimensions of the electrodes are from about 10 nanometers to about 5 microns.

12. A method of forming a composite material comprising:
forming a conductor layer;
forming a semiconductor or semimetal layer on the conductor layer;
forming an insulator layer on the conductor layer;
forming an array of two dimensional electrodes with anisotropic geometrical shapes on the insulator layer wherein the anisotropic geometrical shapes have a base length that is longer than a peak length along a principal axis of the electrodes in a first direction of energy flow wherein the peak length is upstream in the energy flow and the base length is downstream in the energy flow in the composite material such that, when a voltage is applied between the electrodes and conductor layer, the regions under the electrodes become insulating and interact with the energy flow in the composite material such that conductivity of energy through the composite material is greater in the first direction than in a second opposite direction.

13. The method of claim 12, wherein the electrodes with anisotropic shapes are dispersed in single or multiple rows oriented perpendicular to the principal direction of energy flow in the material.

14. The method of claim 13, wherein the spacing of the rows of electrodes is on an order of a mean free path of the charge carriers in the energy flow.

15. The method of claim 12, wherein a second array of electrodes is formed on the insulator layer with base lengths and peak lengths oriented along a principal axis directly opposite to that of the first axis to manage energy flow in an opposite direction to the first direction.

16. The method of claim 11, wherein the electrodes with anisotropic shapes are triangles, trapezoids, semicircles, or semiellipses.

17. The method of claim 12, wherein the semiconductor or semimetal layer is a n-type or p-type semiconductor.

18. The method of claim 17, wherein the semiconductor or semimetal is selected from the group consisting of graphene, doped silicon, gallium arsenide, gallium antimonide, gallium nitride, aluminum nitride, bismuth telluride, antimony bismuth telluride, bismuth and mixtures thereof.

19. The method of claim 12, wherein the semiconductor or semimetal is a thermoelectric material and the composite has a ZT figure of merit greater than 0.5 at room temperature.

20. The method of claim 12, wherein the major dimensions of the electrodes are in a range from 10 nanometers to about 5 microns.
